(19) United States
(12) Patent Application Publication
(10) Pub. No.: US 2011/0292740 A1
(43) Pub. Date: Dec. 1, 2011

(54) SEMICONDUCTOR DEVICE AND METHOD FOR OPERATING THE SAME

(76) Inventors: Hee-Jin Byun, Gyeonggi-do (KR); Jong-Chern Lee, Gyeonggi-do (KR)

(21) Appl. No.: 12/949,143

(22) Filed: Nov. 18, 2010

(30) Foreign Application Priority Data
May 28, 2010 (KR) 10-2010-0050478

(51) Int. Cl. G11C 7/10

(52) U.S. Cl. 365/189.05

(57) ABSTRACT

A semiconductor device includes a data alignment unit configured to align serial input data in response to a data strobe signal, a data latching unit configured to latch an output signal of the data alignment unit in response to first and second synchronization pulse signals which are activated according to BL information during a write operation, and a data output unit configured to output an output signal of the data latching unit to a plurality of global data lines in response to a data input strobe signal corresponding to the BL information.

### CROSS-REFERENCE TO RELATED APPLICATIONS

The present application claims priority of Korean Patent Application No. 10-2010-0050478, filed on May 28, 2010, which is incorporated herein by reference in its entirety.

### BACKGROUND OF THE INVENTION

Exemplary embodiments of the present invention relate to semiconductor design technology, and more particularly, to a semiconductor device which aligns a plurality of serial input data applied according to a burst length (BL) and outputs the aligned data as parallel output data.

In general, a semiconductor device, including double data rate synchronous DRAM (DDR SDRAM) has several million memory cells for storing data. The semiconductor device may store or output data according to a command from a central processing unit (CPU). That is, when the CPU requests a write operation, the semiconductor device stores data in a memory cell corresponding to an address inputted from the CPU. When the CPU requests a read operation, the semiconductor device outputs data stored in a memory cell corresponding to an address inputted from the CPU. In other words, the data inputted through a data pad is inputted to the memory cell via a data input path during a write operation, and the data stored in the memory cell is outputted to the outside through a data pad via a data output path during a read operation.

Recently developed semiconductor devices operate at high speeds and have large capacities. Accordingly, the number of data which are consecutively inputted through one data pad has gradually increased. Here, the number of consecutively-inputted data, that is, serial input data is generally defined as a burst length (BL). In other words, when the BL is four, the number of serial input data corresponds to four bits, and when the BL is eight, the number of serial input data corresponds to eight bits. The serial input data inputted according to the BL are converted into parallel output data through an alignment operation, and the parallel output data are outputted to a plurality of global input/output lines which are internal global data lines of the semiconductor device. Therefore, the semiconductor device includes a circuit configured to perform such an alignment operation.

FIG. 1 is a block diagram illustrating a part of the configuration of a conventional semiconductor device.

Referring to FIG. 1, the semiconductor device includes a data alignment unit 110, a data multiplexing unit 120, and a data output unit 130.

The data alignment unit 110 is configured to align serial input data DAT_IN in response to a rising strobe signal DQS_R and a falling data strobe signal DQS_F and output zero-th to third rising aligned data ALGN_R<0:3> and zero-th to third falling aligned data ALGN_F<0:3> in response to a synchronization pulse signal SYC_PUL.

The data multiplexing unit 120 is configured to output the zero-th to third rising aligned data ALGN_R<0:3> and the zero-th to third falling aligned data ALGN_F<0:3> to output paths which are selected according to burst length information INF_BL. In other words, when the BL is eight, the zero-th to third rising aligned data ALGN_R<0:3> and the zero-th to third falling aligned data ALGN_F<0:3> are transferred to zero-th to seventh global input/output lines GIO<0:7>, respectively, through the data output unit 130. When the BL is four, the zero-th and first rising aligned data ALGN_R<0:1> and the zero-th and first falling aligned data ALGN_F<0:1> are transferred to the zero-th to third global input/output lines GIO<0:3> through the data output unit 130. At this time, the zero-th and first rising aligned data ALGN_R<0:1> and the zero-th and first falling aligned data ALGN_F<0:1> are also transferred to the fourth to seventh input/output lines GIO<4:7> as in the zero-th to third global input/output lines GIO<0:3>.

Meanwhile, the data output unit 130 is configured to synchronize the output signals of the data multiplexing unit 120 with a data input strobe signal DIN_STBP and outputs the synchronized signals to the zero-th to seventh global input/output lines GIO<0:7>.

FIG. 2 is a block diagram illustrating the data alignment unit 110 of FIG. 1.

Referring to FIG. 2, the data alignment unit 110 includes first to eleventh synchronization sections 210R, 220R, 230R, 240R, 250R, 210F, 220F, 230F, 240F, and 250F.

The first synchronization section 210R is configured to synchronize the serial input data DAT_IN with the rising strobe signal DQS_R and output the synchronized data. The second synchronization section 220R is configured to synchronize the output signal of the first synchronization section 210R with a falling strobe signal DQS_F and output the synchronized signal as the third rising aligned data ALGN_R<3>. The third synchronization section 230R is configured to synchronize the third rising aligned data ALGN_R<3> with the rising strobe signal DQS_R and output the synchronized data. The fourth synchronization section 240R is configured to synchronize the output signal of the third synchronization section 230R with the falling strobe signal DQS_F and output the synchronized signal as the second rising aligned data ALGN_R<2>. The fifth synchronization section 250R is configured to synchronize the second rising aligned data ALGN_R<2> with a synchronization pulse signal SYN_PUL and output the synchronized data as the zero-th rising aligned data ALGN_R<0>. The sixth synchronization section 260R is configured to synchronize the rising aligned data ALGN_R<3> with the synchronization pulse signal SYC_PUL and output the synchronized data as the first rising aligned data ALGN_R<1>.

The seventh synchronization section 210F is configured to synchronize the serial input data DAT_IN with the falling strobe signal DQS_F and output the synchronized data as the third falling aligned data ALGN_F<3>. The eighth synchronization section 220F is configured to synchronize the third falling aligned data ALGN_F<3> with the rising strobe signal DQS_R and output the synchronized data. The ninth synchronization section 230F is configured to synchronize the output signal of the eighth synchronization section 220F with the falling strobe signal DQS_F and output the synchronized signal as the second falling aligned data ALGN_F<2>. The tenth synchronization section 240F is configured to synchronize the second falling aligned data ALGN_F<2> with the synchronization pulse signal SYC_PUL and output the synchronized data as the zero-th falling aligned data ALGN_F<0>. The eleventh synchronization section 250F is configured to synchronize the third falling aligned data ALGN_F<3> with the synchronization pulse signal SYC_PUL and output the synchronized data as the first falling aligned data ALGN_F<1>.

FIG. 3 is a waveform diagram illustrating the operation waveform of the data alignment unit 110 of FIG. 2. For convenience of explanation, a case in which the BL is eight will be taken as an example. Accordingly, the serial input data DAT_IN includes zero-th to seventh input data.

Referring to FIGS. 2 and 3, the first synchronization section 210R outputs zero-th input data which is the first data of the serial input data DAT_IN, in response to the rising strobe signal DQS_R. Then, the second synchronization section 220R and the seventh synchronization section 210F output the zero-th input data and first input data (i.e., the next inputted data of DAT_IN), respectively, in response to the falling strobe signal DQS_F. Thus, the third rising aligned data ALGN_R<3> becomes the zero-th input data, and the third falling aligned data ALGN_F<3> becomes the first input data.

Second and third input data which are then inputted also become the third rising aligned data ALGN_R<3> and the third falling aligned data ALGN_F<3>, respectively, through the above-described operation. At this time, the zero-th input data of the third rising aligned data ALGN_R<3> becomes the second rising aligned data ALGN_R<2> through the third and fourth synchronization sections 230R and 240R, and the first input data of the third falling aligned data ALGN_F<3> becomes the second falling aligned data ALGN_F<2> through the eighth and ninth synchronization sections 220F and 230F.

Subsequently, the synchronization pulse signal SYC_PUL is activated. Accordingly, the second rising aligned data ALGN_R<2>, the second falling aligned data ALGN_F<2>, the third rising aligned data ALGN_R<3>, and the third falling aligned data ALGN_F<3> are outputted as the zero-th rising aligned data ALGN_R<1>, the zero-th falling aligned data ALGN_F<0>, the first rising aligned data ALGN_R<1>, and the first falling aligned data ALGN_F<1>, respectively. That is, the fifth synchronization section 250R outputs the zero-th input data as the zero-th rising aligned data ALGN_R<0> in response to the synchronization pulse signal SYC_PUL, and the sixth synchronization section 260R outputs the second input data as the first rising aligned data ALGN_R<1> in response to the synchronization pulse signal SYC_PUL. Furthermore, the tenth synchronization section 240F outputs the first input data as the zero-th falling aligned data ALGN_F<0>, and the eleventh synchronization section 250F outputs the third input data as the first falling aligned data ALGN_F<1>.

After that, fourth to seventh input data are consecutively inputted, and aligned through the above-described operation. At this time, the data multiplexing unit 120 outputs the zero-th to third input data, which are the zero-th rising aligned data ALGN_R<0>, the zero-th falling aligned data ALGN_F<0>, the first rising aligned data ALGN_R<1>, and the first falling aligned data ALGN_F<1>, respectively, and the fourth to seventh input data, which are the second rising aligned data ALGN_R<2>, the second falling aligned data ALGN_F<2>, the third rising aligned data ALGN_R<3>, and the third falling aligned data ALGN_F<3>, respectively, to the data multiplexing unit 120.

Returning to FIG. 1, the zero-th to third rising aligned data ALGN_R<0:3> and the zero-th to third falling aligned data ALGN_F<0:3>, which are aligned in such a manner, are inputted to the data multiplexing unit 120, and the data multiplexing unit 120 outputs the zero-th to third rising aligned data ALGN_R<0:3> and the zero-th to third falling aligned data ALGN_F<0:3> to the corresponding output terminals according to the BL information INF_BL. Subsequently, the data output unit 130 outputs the respective input signals to the zero-th to seventh global input/output lines GIO<0:7> in response to the data input strobe signal DIN_STBP. That is, the zero-th to seventh input data which have been inputted in series are outputted as the zero-th to seventh output data DAT_OUT<0:7>.

When the BL is four, the data multiplexing unit 120 outputs the zero-th and first rising aligned data ALGN_R<0:1> and the zero-th and first falling aligned data ALGN_F<0:1> to the data output unit 130 corresponding to the zero-th to third global input/output lines GIO<0:3>, and also outputs the zero-th and first rising aligned data ALGN_R<0:1> and the zero-th and first falling aligned data ALGN_F<0:1> to the data output unit 130 corresponding to the fourth to seventh global input/output lines GIO<4:7>, which are the remaining global input/output lines. Therefore, the zero-th to third global input/output lines GIO<0:3> and the fourth to seventh global input/output lines GIO<4:7> output the same data, that is, the zero-th and first rising aligned data ALGN_R<0:1> and the zero-th and first falling aligned data ALGN_F<0:1>.

Meanwhile, Joint Electron Device Engineering Council (JEDEC) which is an international organization for standardization has defined a variety of standards for the operations of semiconductor devices. The standards may include suggesting a tDQSS which defines a margin that may occur in a data strobe signal and an external clock signal. The data strobe signal is a source signal of the rising data strobe signal DQS_R and the falling data strobe signal DQS_F, and tDQSS is defined as ±0.25 tCK of 1 tCK corresponding to the external clock signal, where 1 tCK is the period of the external clock signal.

Referring to FIG. 3, the data input strobe signal DIN_STBP synchronizes the second and third rising/falling aligned data ALGN_R<2:3> and ALGN_F<2:3>. At this time, a duration for which the data input strobe signal DIN_STBP may be activated is ideally 1 tCK for ideal. However, when tDQSS is considered, a duration for which the data input strobe signal DIN_STBP may be activated becomes 0.5 tCK. In a recent situation in which the operation frequency of recent semiconductor devices is increased, a period corresponding to 1 tCK of an external clock signal gradually decreases. This means that the period during which the data input strobe signal DIN_STBP may be activated gradually decreases. Furthermore, the zero-th to third rising aligned data ALGN_R<0:3> and the zero-th to third falling aligned data ALGN_F<0:3> pass through the data multiplexing unit 120. This serves as a factor which further reduces the margin of the data input strobe signal DIN_STBP. The reduction in the margin of the data input strobe signal DIN_STBP may result in the aligned data not being recognized normally. In this case, the reliability of the semiconductor device clearly decreases.

FIG. 4 is a circuit diagram illustrating the data output unit 130 of FIG. 1. For convenience of explanation, the following description focuses on portions of the circuit corresponding to the zero-th rising aligned data ALGN_R<0> among the zero-th to third rising aligned data ALGN_R<0:3> and the zero-th to third falling aligned data ALGN_F<0:3>.

FIG. 4 illustrates a latch-type amplification unit 410 and a driving unit 420. The latch-type amplification unit 410 is cross-coupled to latch the zero-th rising aligned data ALGN_R<0>, and the driving unit 420 receives output signals OUT and OUTB of the amplification unit 410 to drive the zero-th global input/output line GIO<0>.

In general, the cross-coupled latch-type amplification unit 410 occupies a large area. In the conventional configuration, however, the margin of the input strobe signal DIN_STBP is small. Therefore, the cross-coupled latch-type amplification unit 410 capable of latching the edge of the zero-th rising aligned data ALGN_R<0> is commonly used. Thus, the cross-coupled latch-type amplification unit 410 occupying a large area may be a burden when designing a semiconductor device.

### SUMMARY OF THE INVENTION

Exemplary embodiments of the present invention are directed to a semiconductor device capable of latching a plurality of aligned data in response to a plurality of synchronization pulse signals corresponding to a BL.

Another exemplary embodiment of the present invention is directed to a semiconductor device from which a circuit for multiplexing aligned data according to a BL is removed.

Another exemplary embodiment of the present invention is directed to a semiconductor device capable of simplifying the configuration of a circuit for driving a plurality of global data lines.

In accordance with an exemplary embodiment of the present invention, a semiconductor device includes a data alignment unit configured to align serial input data in response to a data strobe signal, a data latching unit configured to latch an output signal of the data alignment unit in response to first and second synchronization pulse signals which are activated according to BL information during a write operation, and a data output unit configured to output an output signal of the data latching unit to a plurality of global data lines in response to a data input strobe signal corresponding to the BL information.

In accordance with another exemplary embodiment of the present invention, there is provided a method for operating a semiconductor device which outputs a plurality of data, which are aligned in response to a data strobe signal, to a plurality of global data lines in response to a data input strobe signal. The method includes latching the plurality of aligned data by activating first and second synchronization pulse signals at the same time before the data input strobe signal, corresponding to a first burst length (BL), is activated, and latching the plurality of aligned data by sequentially activating the first and second synchronization pulse signals at different times before the data input strobe signal, corresponding to a second BL, is activated.

In accordance with yet another exemplary embodiment of the present invention, a semiconductor device includes a data alignment unit configured to align serial input data in response to a data strobe signal, and a data latching output unit configured to latch an output signal of the data alignment unit in response to first and second synchronization pulse signals which are activated according to BL is information during a write operation, and output the latched data to a plurality of global data lines in response to a data input strobe signal.

### BRIEF DESCRIPTION OF THE DRAWINGS

FIG. 1 is a block diagram illustrating a part of the configuration of a conventional semiconductor device.

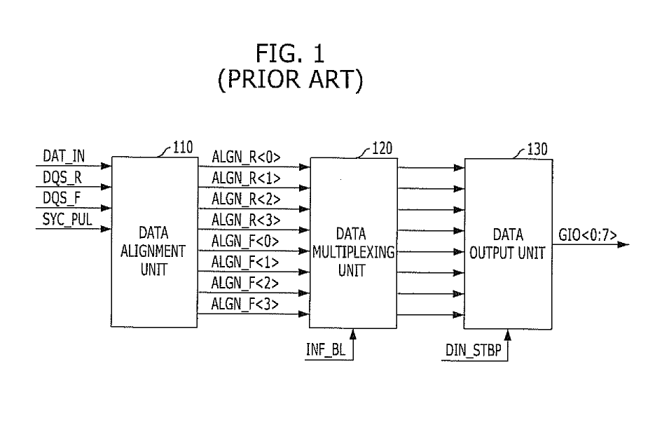

FIG. 2 is a block diagram illustrating a data alignment unit of FIG. 1.

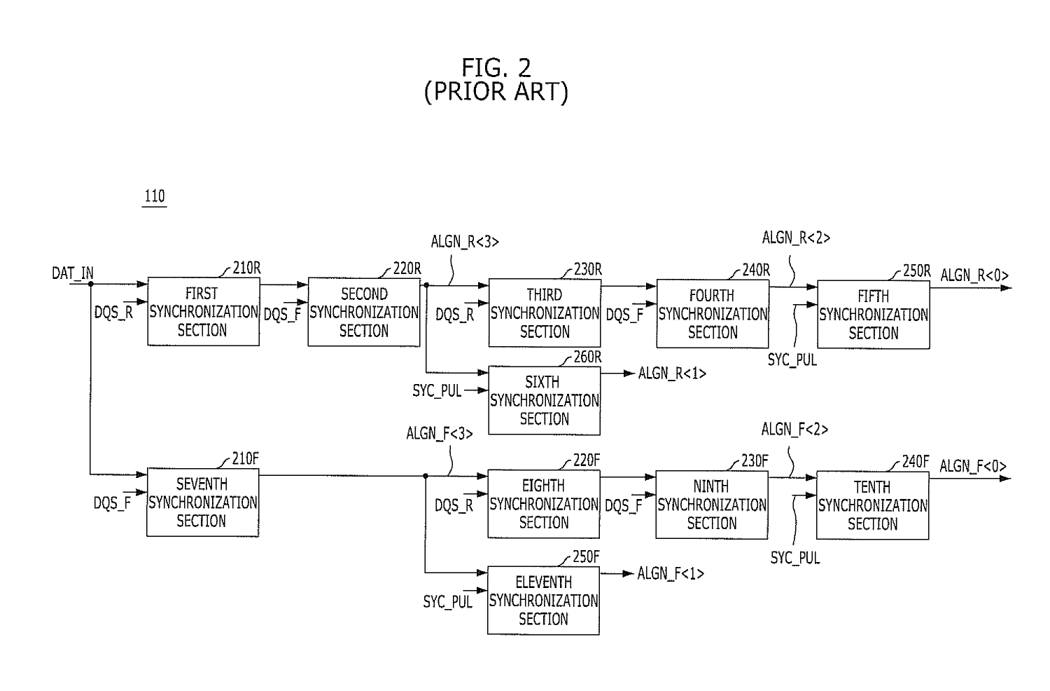

FIG. 3 is a waveform diagram illustrating the operation waveform of the data alignment unit of FIG. 2

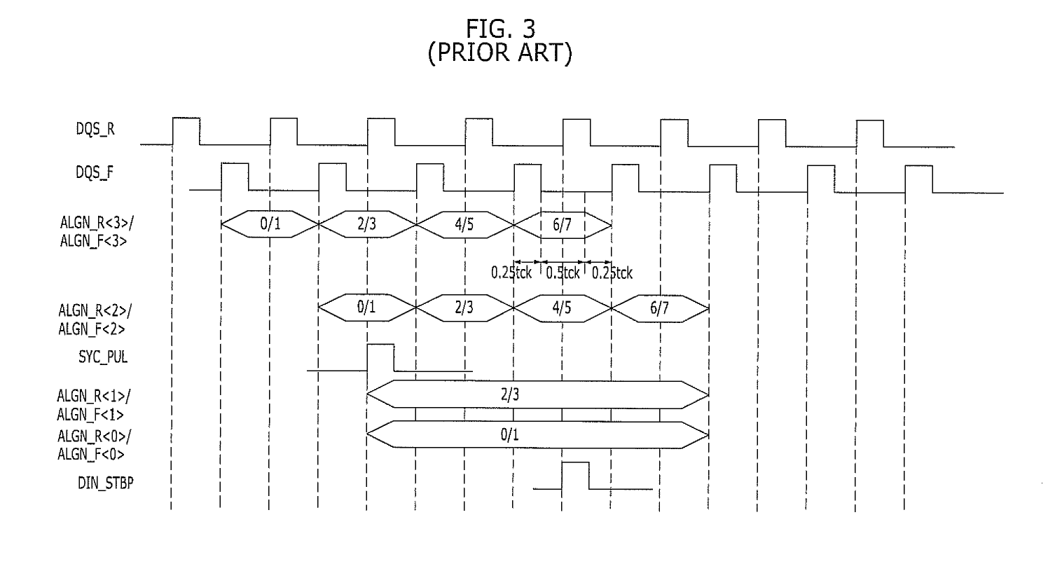

FIG. 4 is a circuit diagram illustrating a data output unit of FIG. 1.

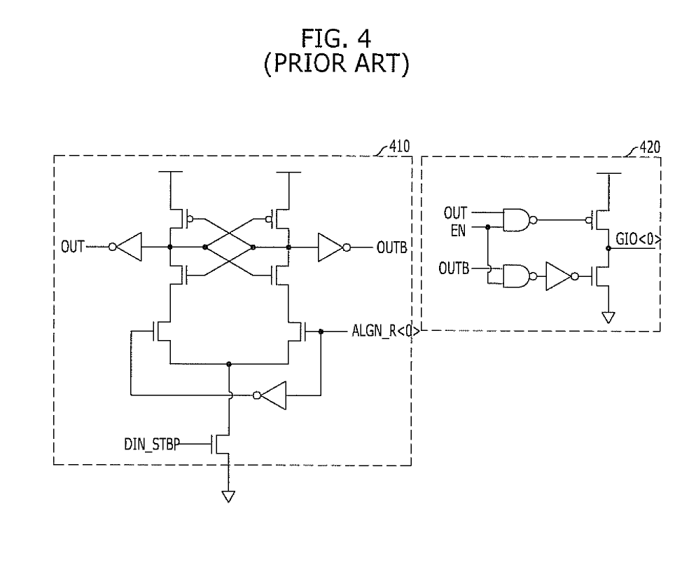

FIG. 5 is a block diagram illustrating a part of the configuration of a semiconductor device in accordance with an exemplary embodiment of the present invention.

FIG. 6 is a block diagram illustrating a data alignment unit of FIG. 5.

FIG. 7 is a circuit diagram illustrating a data latching unit of FIG. 5.

FIG. 8 is a circuit diagram illustrating a data output unit of FIG. 5.

FIG. 9 is a timing diagram illustrating the circuit operation of the semiconductor device in accordance with an exemplary embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

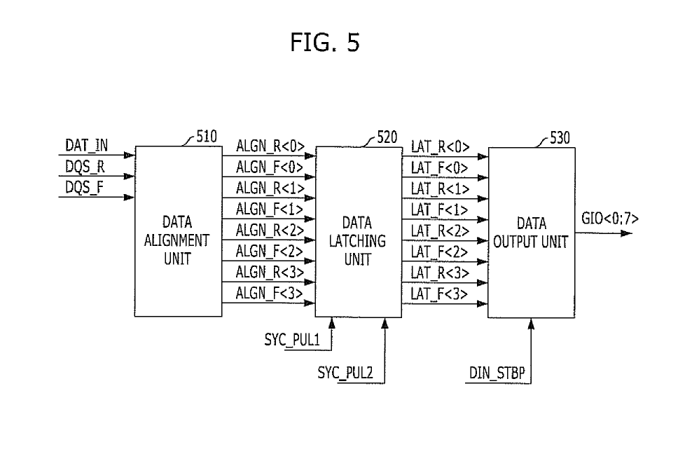

FIG. 5 is a block diagram illustrating a part of the configuration of a semiconductor device in accordance with an exemplary embodiment of the present invention.

Referring to FIG. 5, the semiconductor device includes a data alignment unit 510, a data latching unit 520, and a data output unit 530.

The data alignment unit 510 is configured to align serial input data DAT_IN in response to a rising data strobe signal DQS_R and a falling data strobe signal DQS_F, and output the aligned data as zero-th to third rising aligned data ALGN_R<0:3> and zero-th to third falling aligned data ALGN_F<0:3>. Here, the rising data strobe signal DQS_R and the falling data strobe signal DQS_F are generated by buffering a data strobe signal which is transferred from a CPU. The data strobe signal is not illustrated in FIG. 5.

The data latching unit 520 is configured to latch the zero-th to third rising aligned data ALGN_R<0:3> and the zero-th to third falling aligned data ALGN_F<0:3> in response to first and second synchronization pulse signals SYC_PUL1 and SYC_PUL2 which are activated at a time corresponding to BL information during a write operation, and output zero-th to third rising latched data LAT_R<0:3> and zero-th to third falling latched data LAT_F<0:3>. Here, the first and second synchronization pulse signals SYC_PUL1 and SYC_PUL2 are activated by an external clock signal at a time corresponding to BL information during a write operation. The external clock signal is not illustrated in FIG. 5.

The data output unit 530 is configured to output the zero-th to third rising latched data LAT_R<0:3> and the zero-th to third falling latched data LAT_F<0:3>, which are outputted from the data latching unit 520, to zero-th to seventh global input/output lines GIO<0:7> in response to a data input strobe signal DIN_STBP. Here, the data input strobe signal DIN_STBP is activated by an external clock signal at a time corresponding to BL information during a write operation.

In other words, the data latching unit 520 and the data output unit 520 in accordance with an exemplary embodiment of the present invention, which are hereafter referred to as ‘data latching output unit’, latch the zero-th to third rising aligned data ALGN_R<0:3> and the zero-th to third falling aligned data ALGN_F<0:3> in response to the first and second synchronization pulse signals SYC_PUL1 and SYC_PUL2 during the write operation, and output the zero-th to third rising latched data LAT_R<0:3> and the zero-th to third falling latched data LAT_F<0:3> to the zero-th to seventh global input/output lines GIO<0:7> in response to the data input strobe signal DIN_STBP. As described in more detail below, a circuit for performing a multiplexing operation, which has been provided in the conventional semiconductor device, may be omitted due to an operation of the data latching output unit.

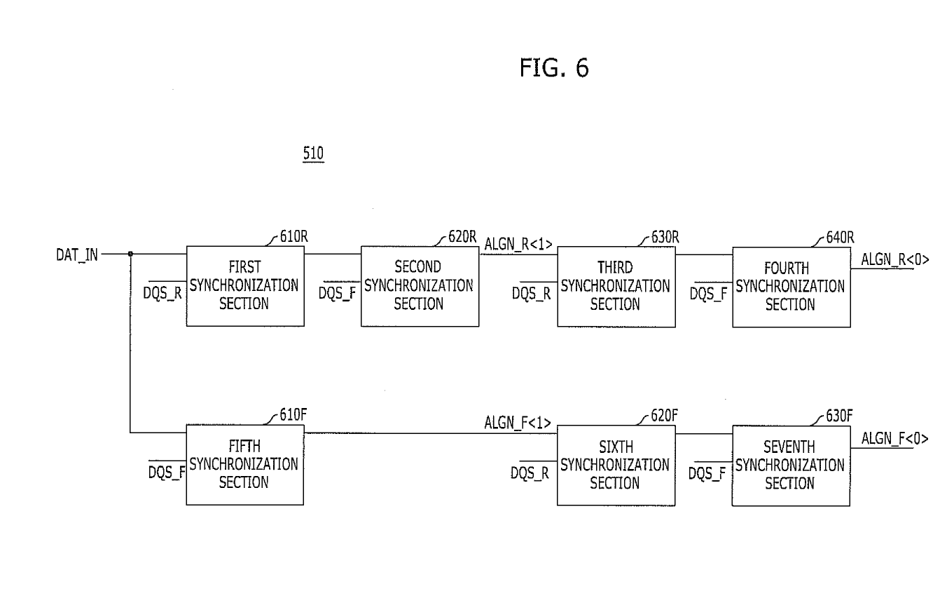

FIG. 6 is a block diagram illustrating the data alignment unit 510 of FIG. 5.

Referring to FIG. 6, the data alignment unit 510 includes first to seventh synchronization sections 610R, 620R, 630R, 640R, 610F, 620F, and 630F. The first to seventh synchronization sections 610R, 620R, 630R, 640R, 610F, 620F, and 620F are provided to shift the serial input data DAT_IN in response to the rising data strobe signal DQS_R and the falling data strobe signal DQS_F.

The first synchronization section 610R is configured to synchronize the serial input data DAT_IN with the rising data strobe signal DQS_R and output the synchronized signal. The second synchronization section 620R is configured to synchronize the output signal of the first synchronization section 610R with the falling data strobe signal DQS_F and output the synchronized signal as the first rising aligned data ALGN_R<1>. The third synchronization section 630R is configured to synchronize the first rising aligned data ALGN_R<1> with the rising data strobe signal DQS_R and output the synchronized data. The fourth synchronization section 640R is configured to synchronize the output signal of the third synchronization section 630R with the falling data strobe signal DQS_F and output the synchronized signal as the zero-th rising aligned data ALGN_R<0>.

The fifth synchronization section 610F is configured to synchronize the serial input data DAT_IN with the falling data strobe signal DQS_F and output the synchronized data as the first falling aligned data ALGN_F<1>. The sixth synchronization section 620F is configured to synchronize the first falling aligned data ALGN_F<1> with the rising data strobe signal DQS_R and output the synchronized data. The seventh synchronization section 630F is configured to synchronize the output signal of the sixth synchronization section 620F with the falling data strobe signal DQS_F and output the synchronized signal as the zero-th failing aligned data ALGN_F<0>.

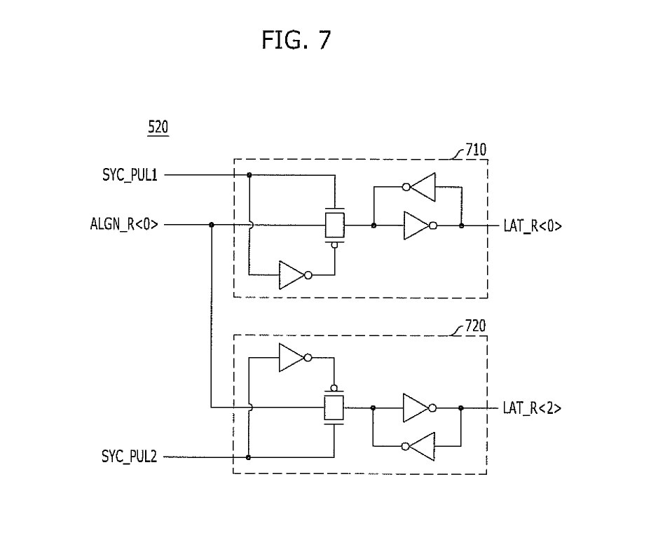

FIG. 7 is a circuit diagram illustrating the data latching unit 520 of FIG. 5. For convenience of explanation, the following description focuses on a portion of the circuit corresponding to the zero-th rising aligned data ALGN_R<0>. It should be understood that other portions of the circuit corresponding to other signals are configured similarly.

Referring to FIG. 7, the data latching unit 520 includes a first latching section 710 and a second latching section 720. The first latching section 710 is configured to latch the zero-th rising aligned data ALGN_R<0> in response to the first synchronization pulse signal SYC_PUL1 and output the latched data as the zero-th rising latched data LAT_R<0>. The second latching section 720 is configured to latch the zero-th rising aligned data ALGN_R<0> in response to the second synchronization pulse signal SYC_PUL2 and output the latched data as the second rising latched data LAT_R<2>. As described below, the first and second synchronization signals SYC_PUL1 and SYC_PUL2 are simultaneously activated at a scheduled time when the BL is four, or sequentially activated at a scheduled time when the BL is eight.

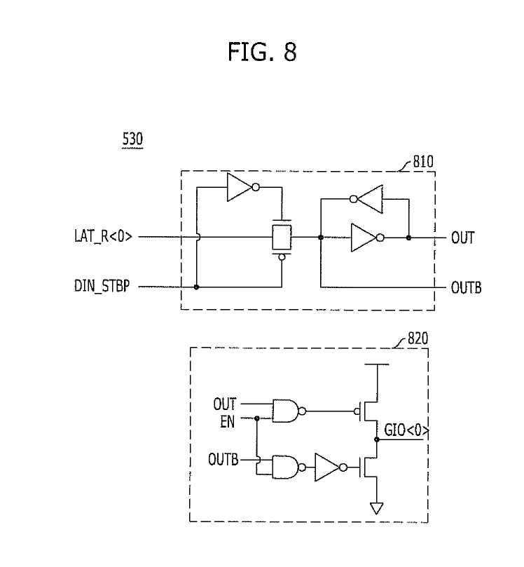

FIG. 8 is a circuit diagram illustrating the data output unit 530 of FIG. 5. For convenience of explanation, the following description focuses on a portion of the circuit corresponding to the zero-th rising latched data LAT_R<0>. It should be understood that other portions of the circuit corresponding to other signals are configured similarly.

Referring to FIG. 8, the data output unit 530 includes a synchronization section 810 and a driving section 820. The synchronization section 810 is configured to synchronize the zero-th rising latched data LAT_R<0> with the data input strobe signal DIN_STBP and output the synchronized data as first and second output signals OUT and OUTB. The driving section 820 is configured to drive the global input/output line GIO<0> in response to the first and second output signals OUT and OUTB. As described below, the circuit for the synchronization operation of the data input strobe signal DIN_STBP may be configured as illustrated in the synchronization section 810, having a relatively small size. The margin of the data input strobe signal DIN_STBP is sufficient in the semiconductor memory device in accordance with an exemplary embodiment of the present invention. For reference, an enable signal EN for controlling the driving section 820 is a signal which is activated during the write operation.

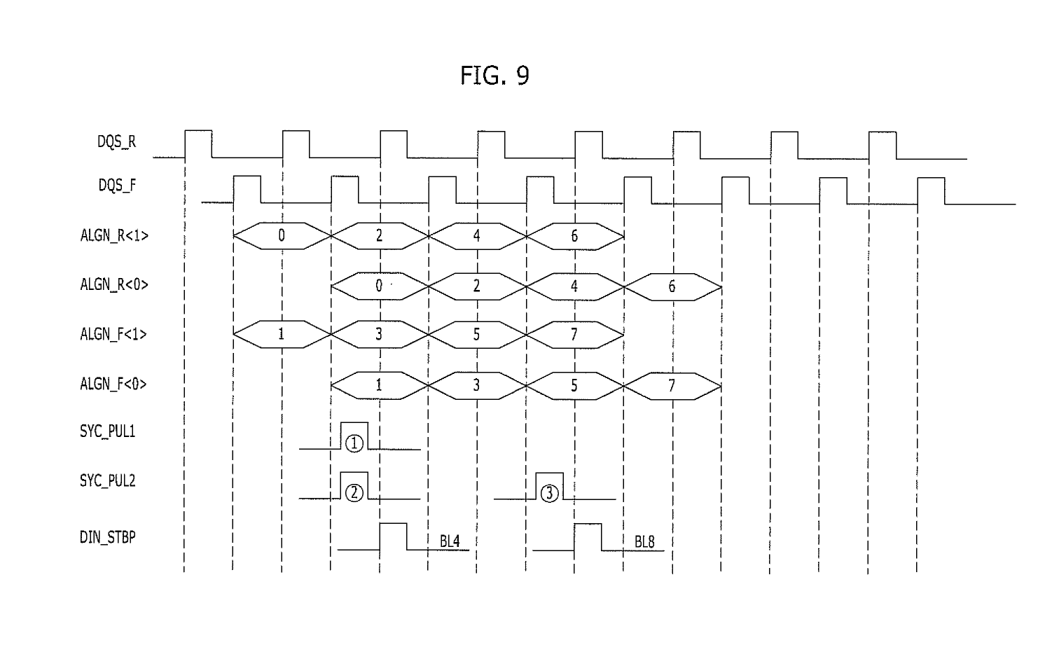

FIG. 9 is a timing diagram illustrating the circuit operation of the semiconductor device in accordance with an exemplary embodiment of the present invention.

Referring to FIGS. 6 to 9, zero-th input data which is the first data of the serial input data DAT_IN is outputted from the first synchronization section 610R in response to the rising strobe signal DQS_R. Subsequently, the second and fifth synchronization sections 620R and 610F output the zero-th input data and first input data (i.e., the next inputted data of DAT_IN), respectively, in response to the falling strobe signal DQS_F. Thus, the first rising aligned data ALGN_R<1> becomes the zero-th input data, and the first falling aligned data ALGN_F<1> becomes the first input data.

Second and third input data, which are then inputted, become the first rising aligned data ALGN_R<1> and the first falling aligned data ALGN_F<1>, respectively, through the above-described operation. At this time, the zero-th input data of the first rising aligned data ALGN_R<1> becomes the zero-th rising aligned data ALGN_R<0> through the third and fourth synchronization sections 630R and 640R, and the first input data of the first falling aligned data ALGN_F<1> becomes the zero-th falling aligned data ALGN_F<0> through the sixth and seventh synchronization sections 620F and 630F.

When the BL is four, the first and second synchronization pulse signals SYC_PUL1 and SYC_PUL2 are activated at the same time (see labels \textcircled{1} and \textcircled{2} in FIG. 9). Referring to FIG. 7, when the first and second synchronization pulse signals SYC_PUL1 and SYC_PUL2 are activated at the same time, the zero-th rising aligned data ALGN_R<0> is outputted as the zero-th and second rising latched data LAT_R<0> and LAT_R<2>. The first rising aligned data ALGN_R<1> and the zero-th and first falling aligned data ALGN_F<0> and ALGN_F<1> are subjected to the same operation. That is, the zero-th input data is outputted as the zero-th and second rising latched data LAT_R<0> and LAT_R<2>, the first input data is outputted as the zero-th and second falling latched data LAT_F<0> and LAT_F<2>, the second input data is outputted as the first and third rising latched data LAT_R<1> and LAT_R<3>, and the third input data is outputted as the first and third falling latched data LAT_F<1> and LAT_F<3>.

Then, the data output unit 530 synchronizes the zero-th to third rising latched data LAT_R<0:3> and the zero-th to third falling latched data LAT_F<0:3>, which are outputted by the data latching unit 520, with a data input strobe signal BL4 corresponding to the serial input data DAT_IN having a BL of four. The data output unit 530 also outputs the synchronized data to the zero-th to seventh global input/output lines GIO<0:7>. Accordingly, the semiconductor memory device in accordance with an exemplary embodiment of the present invention may perform the operation according to desired specifications.

Next, when the BL is eight, the zero-th to third input data are aligned by the above-described method. Once the zero-th to third input data are aligned, the first synchronization pulse signal SYC_PUL1 is activated at a scheduled time (see label \textcircled{1} in FIG. 9). Returning to FIG. 7, the zero-th input data which is the zero-th rising aligned data ALGN_R<0> is outputted as the zero-th rising latched data LAT_R<0> in response to the first synchronization pulse signal SYC_PUL1. Similarly, the first input data is outputted as the zero-th falling latched data LAT_F<0>, the second input data is outputted as the first rising latched data LAT_R<1>, and the third input data is outputted as the first falling latched data LAT_F<1>.

After that, the fourth to seventh input data are aligned according to the above-described method. Once the fourth to seventh input data are aligned, the second synchronization pulse signal SYC_PUL2 is activated at a scheduled time (see label \textcircled{3} in FIG. 9). Therefore, the fourth input data which is the zero-th rising aligned data ALGN_R<0> is outputted as the rising latched data LAT_R<2> in response to the second synchronization pulse signal SYC_PUL2. Similarly, the fifth input data is outputted as the second falling latched data LAT_F<2>, the sixth input data is outputted as the third rising latched data LAT_F<3>, and the seventh input data is outputted as the third falling latched data LAT_F<3>. That is, the zero-th, second, fourth, and sixth input data are outputted as the zero-th to third rising latched data LAT_R<0:3>, and the first, third, fifth, and seventh input data are outputted as the zero-th to third falling latched data LAT_F<0:3>.

Then, the data output unit 530 synchronizes the zero-th to third rising latched data LAT_R<0:3> and the zero-th to third falling latched data LAT_F<0:3>, which are outputted from the data latching unit 520, with a data input strobe signal BL8 corresponding to serial input data DAT_IN having a BL of eight, and outputs the synchronized data to the zero-th to seventh global input/output lines GIO<0:7>.

As shown in FIG. 9, the semiconductor device in accordance with an exemplary embodiment of the present invention activates the first and second synchronization pulse signals SYC_PUL1 and SYC_PUL2 at the same scheduled time (see labels \textcircled{1} and \textcircled{2}), before the data input strobe signal BL4 corresponding to the BL of four is activated. Therefore, the zero-th rising aligned data ALGN_R<0>, the zero-th falling aligned data ALGN_F<0>, the first rising aligned data ALGN_R<1>, and the first falling aligned data ALGN_F<1> are latched by the first and second synchronization pulse signals SYC_PUL1 and SYC_PUL2. This means that the margin of the data input strobe signal BL4 may be sufficiently secured.

Furthermore, the semiconductor device latches the zero-th rising aligned data ALGN_R<0>, the zero-th falling aligned data ALGN_F<0>, the first rising aligned data ALGN_R<1>, and the first falling aligned data ALGN_F<1> in response to the first synchronization pulse signal SYC_PUL1 (see label \textcircled{1}) before the data input strobe signal BL8 corresponding to the BL of eight is activated. Then, the semiconductor device latches the zero-th rising aligned data ALGN_R<0>, the zero-th falling aligned data ALGN_F<0>, the first rising aligned data ALGN_R<1>, and the first falling aligned data ALGN_F<1> in response to the second synchronization pulse signal SYC_PUL2 (see label \textcircled{3}) which is sequentially activated after the first synchronization pulse signal SYC_PUL1. This also means that the margin of the data input strobe signal BL8 may be sufficiently secured.

As described above, the semiconductor device in accordance with an exemplary embodiment of the present invention latches the aligned data, and thus secures a sufficient margin of the data input strobe signal DIN_STBP, thereby guaranteeing a stable operation of the circuit. Furthermore, such a sufficient margin of the data input strobe signal DIN_STBP may serve to simplify the circuit configuration of the data output unit 530. This may reduce the area occupied by the circuit, thereby increasing net die. Furthermore, in the conventional circuit configuration, the margin of the data input strobe signal DIN_STBP is further reduced by the circuit for multiplexing operation. In an exemplary embodiment of the present invention, however, the circuit for multiplexing operation may be removed, and the operation according to desired specifications is normally performed by the latching operation. Therefore, the margin of the data input strobe signal DIN_STBP increases.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a data alignment unit configured to align serial input data in response to a data strobe signal;
a data latching unit configured to latch an output signal of the data alignment unit in response to first and second synchronization pulse signals which are activated according to burst length (BL) information during a write operation; and
a data output unit configured to output an output signal of the data latching unit to a plurality of global data lines in response to a data input strobe signal corresponding to the BL information.

2. The semiconductor device of claim 1, wherein the first and second synchronization pulse signals are simultaneously activated at a time in response to the BL information having a first value, and sequentially activated at times in response to the BL information having a second value.

3. The semiconductor device of claim 1, wherein the data alignment unit comprises a plurality of synchronization sections configured to shift the serial input data by synchronizing the serial input data with the data strobe signal.

4. The semiconductor device of claim 1, wherein the data latching unit comprises:
a first latching unit configured to latch the output signal of the data alignment unit in response to the first synchronization pulse signal; and
a second latching unit configured to latch the output signal of the data alignment unit in response to the second synchronization pulse signal.

5. The semiconductor device of claim 1, wherein the data output unit comprises:
a synchronization section configured to synchronize the output signal of the data latching unit with the data input strobe signal and output the synchronized signal; and
a driving section configured to drive the plurality of global data lines in response to the output signal of the synchronization section.

6. A method for operating a semiconductor device which outputs a plurality of data, which are aligned in response to a data strobe signal, to a plurality of global data lines in response to a data input strobe signal, the method comprising:
latching the plurality of aligned data by activating first and second synchronization pulse signals at the same time before the data input strobe signal, corresponding to a first burst length (BL), is activated; and
latching the plurality of aligned data by sequentially activating the first and second synchronization pulse signals at different times before the data input strobe signal, corresponding to a second BL, is activated.

7. The method of claim 6, further comprising outputting the latched aligned data to the plurality of global data lines in response to the data input strobe signal.

8. The method of claim 6, wherein the plurality of global data lines are divided into a first global data line group and a second global data line group,
the same input data are transferred to the first and second global data line groups in response to the data input strobe signal corresponding to the first BL, and
different input data are transferred to the first and second global data line groups in response to the data input strobe signal corresponding to the second BL.

9. A semiconductor device comprising:
a data alignment unit configured to align serial input data in response to a data strobe signal; and
a data latching output unit configured to latch an output signal of the data alignment unit in response to first and second synchronization pulse signals which are activated according to BL information during a write operation, and output the latched data to a plurality of global data lines in response to a data input strobe signal.

10. The semiconductor device of claim 9, wherein the first and second synchronization pulse signals are simultaneously activated at a time in response to the BL information having a first value, and are sequentially activated at times in response to the BL information having a second value.

11. The semiconductor device of claim 9, wherein the data alignment unit comprises a plurality of synchronization sections configured to shift the serial input data by synchronizing the serial input data with the data strobe signal.
